(19) United States
(12) Patent Application Publication
(10) Pub. No.: US 2009/0128159 A1
(43) Pub. Date: May 21, 2009

(54) BATTERY PACK ANOMALY DETECTING METHOD AND BATTERY PACK

(76) Inventor: Toshiyuki Nakatsuji, Hyogo (JP)

Correspondence Address: MCDERMOTT WILL & EMERY LLP, 600 13TH STREET, NW, WASHINGTON, DC, 20005-3096, US

(21) Appl. No.: 12/282,965

(22) PCT Filed: Jun. 4, 2007
(86) PCT No.: PCT/JP2007/061298

§ 371 Date: Sep. 15, 2008

(51) Int. Cl. G01N 27/416; G01R 31/36

(52) U.S. Cl. 324/433

(57) ABSTRACT

An anomaly detecting method for a battery pack including a secondary battery made up of at least one cell and a voltage detecting circuit for measuring cell voltage of the secondary battery comprises the steps of measuring the cell voltage, judging by using the measured cell voltage whether predefined anomaly judgment conditions to be used in determining that at least one of an internal short circuit of the cell and an anomaly of the voltage detecting circuit has occurred are satisfied, and determining that at least one of the internal short circuit of the cell and the anomaly of the voltage detecting circuit has occurred if the anomaly judgment conditions are judged to have been satisfied. The anomaly detecting method prevents in advance continued execution of charge operation when the cell voltage does not reach a threshold voltage due to an internal short circuit of the cell or an anomaly of the voltage detecting circuit.

### TECHNICAL FIELD

The present invention relates to a method of detecting a battery pack anomaly and a battery pack and, more particularly, to a method of detecting a battery pack anomaly and a battery pack preferably applied to charging of a secondary lithium battery which requires safety.

### BACKGROUND ART

FIG. 4 is a graph for explaining a typical charging method for the aforementioned secondary lithium battery. The reference symbol al shows changes in voltage of the secondary battery, the reference symbol α2 shows changes in charge current supplied to the secondary battery, and the reference symbol α3 shows the value of the residual capacity in the secondary battery that is indicated on a charger.

First, the aforementioned voltage is in a trickle charge region from the beginning of charging, in which a small constant current I1, such as a charge current of 50 mA, is supplied. This trickle charge operation is continued until cell voltage of one or a plurality of cells reaches an end voltage Vm of the trickle charge operation, such as 2.5 V.

When the aforementioned cell voltage reaches the end voltage Vm, charge process is switched to a constant current (CC) charge region in which an end voltage Vf is applied to charge/discharge terminals of a battery pack until a terminal voltage across the charge terminals reaches a prescribed end voltage Vf of 4.2 V per cell (thus, 12.6 V in the case of three cells connected in series, for example), whereby constant current (CC) charge operation is performed at a prescribed constant current I2 which is a charge current obtained by multiplying 70% of a capacity level 1C dischargeable in one hour when the battery pack is discharged at a constant current from a nominal capacity value NC by the number of parallel-connected cells P.

When the terminal voltage across the aforementioned charge/discharge terminals reaches the end voltage Vf as a consequence, the charge process is switched to a constant voltage (CV) charge region in which the value of the charge current is reduced in such a manner that the terminal voltage does not exceed the end voltage Vf. Then, when the aforementioned charge current value drops down to a foldback current value I3, it is judged that the battery pack has been fully charged, and the charge current is cut off by turning off a field effect transistor (FET) provided in a charge/discharge line, for example. The aforementioned charge control method is found in Patent Document 1, for instance.

If such kind of charge control is exercised in a so-called float charge operation in which a battery pack is built in a load apparatus and is charged by a charger to which the battery pack is connected in parallel with the load apparatus, for example, a phenomenon similar to current foldback (drooping) mentioned above could occur when the charge current decreases as a result of the use of the load apparatus, thus causing a possibility of misjudging that the battery pack has been fully charged. Under such circumstances, Patent Document 2 (paragraph 0004) and Patent Document 3 (paragraph 0030) previously proposed by the applicant of the present invention describe arrangements for judging that the battery pack has been fully charged if the current foldback occurs when the cell voltage is equal to or higher than a specific threshold voltage.

In the aforementioned conventional techniques, however, the battery pack is not judged to have been fully charged if the current foldback occurs when the cell voltage is lower than the threshold voltage, so that the charge operation is not terminated in this case, thus causing a risk of overcharging. The aforementioned current foldback at a cell voltage below the threshold voltage would occur in below-mentioned cases, for example. First, the current foldback at a cell voltage below the threshold voltage would occur if an anomaly occurs in an element in the charge/discharge line, such as an increase in ON-resistance of the FET provided in the charge/discharge line. Second, the current foldback at a cell voltage below the threshold voltage would occur if a charge voltage output from the charger is low. Third, the current foldback at a cell voltage below the threshold voltage would occur if there is an anomaly in an internal circuit of the battery pack and a current flows through a path formed separately from the aforementioned charge/discharge line and only a small amount of current flows through the cell and a current detecting resistor. Fourth, the current foldback at a cell voltage below the threshold voltage would occur if there is an anomaly in a cell voltage detecting circuit. Fifth, the current foldback at a cell voltage below the threshold voltage would occur if there is an anomaly in the cell and its voltage does not increase.

Under such circumstances, the aforementioned Patent Document 2 proposes an arrangement for judging that an anomaly has occurred and then stopping the supply of the charge current if the battery pack is not judged to have been fully charged with reference to the aforementioned current foldback by using the residual capacity in the secondary battery shown by the reference symbol α3 in FIG. 4 even when the charge current has been supplied up to an amount corresponding to a specific capacity equal to or over a rated capacity, that is, 1.5 to 2 times the rated capacity, for example. The indicated residual capacity (RSOC) in the secondary battery is updated as accumulation of the current value begins at a point in time when the charge process is started or when the charge process is switched from trickle charge to constant current (CC) charge (the accumulation begins at the point in time when the charge process is started in FIG. 4). As the charge current is supplied, the current value is accumulated. When the accumulated current value reaches 100% of a maximum value which is the aforementioned rated capacity, this value is maintained. On the other hand, for judging the aforementioned anomaly, the accumulation of the current value continues as long as the charge current is supplied even after the accumulated value has reached the aforementioned 100% value.

The conventional technique described above has a problem that the technique does not allow for a quick response to the occurrence of an anomaly so that a state of overcharge may potentially persist for a long period of time.

On the other hand, if the charge process does not finish even when the time measured from the beginning of charging has exceeded a specific period of time, e.g., 10 hours, it might be possible to judge that an anomaly has occurred and thus terminate the charge process. It is however difficult to set the aforementioned specific period of time and apply this approach to such kind of load apparatus as a personal computer of which battery pack is charged by the aforementioned float charge operation.
Patent Document 1: Japanese Unexamined Patent Publication No. 1994-78471
Patent Document 2: Japanese Patent No. 3546856
Patent Document 3: Japanese Patent No. 3611104

### DISCLOSURE OF THE INVENTION

It is an object of the invention to provide a battery pack anomaly detecting method and a battery pack which make it possible to quickly detect an anomaly when judging that the battery pack has been fully charged based on the fact that cell voltage is equal to or higher than a specific threshold voltage and the value of a charge current has dropped to a specific foldback current value.

In one aspect of the present invention, an anomaly detecting method for a battery pack including a secondary battery made up of at least one cell and a voltage detecting circuit for measuring cell voltage of the secondary battery comprises the steps of measuring the cell voltage, judging by using the measured cell voltage whether predefined anomaly judgment conditions to be used in determining that at least one of an internal short circuit of the cell and an anomaly of the voltage detecting circuit has occurred are satisfied, and determining that at least one of the internal short circuit of the cell and the anomaly of the voltage detecting circuit has occurred if the anomaly judgment conditions are judged to have been satisfied.

In the aforementioned anomaly detecting method, it is judged that at least one of an internal short circuit of the cell and an anomaly of the voltage detecting circuit has occurred by determining whether or not the predefined conditions have been satisfied.

### BRIEF DESCRIPTION OF THE DRAWINGS

FIG. 1 is a block diagram showing the electrical configuration of an electronic system to which an anomaly detecting method according to a first embodiment of the present invention is applied;

FIG. 2 is a flowchart for explaining anomaly detecting operation according to the first embodiment shown in FIG. 1;

FIG. 3 is a flowchart for explaining anomaly detecting operation according to a second embodiment of the present invention; and

FIG. 4 is a graph for explaining a typical example of charge control operation.

### BEST MODES FOR CARRYING OUT THE INVENTION

### First Embodiment

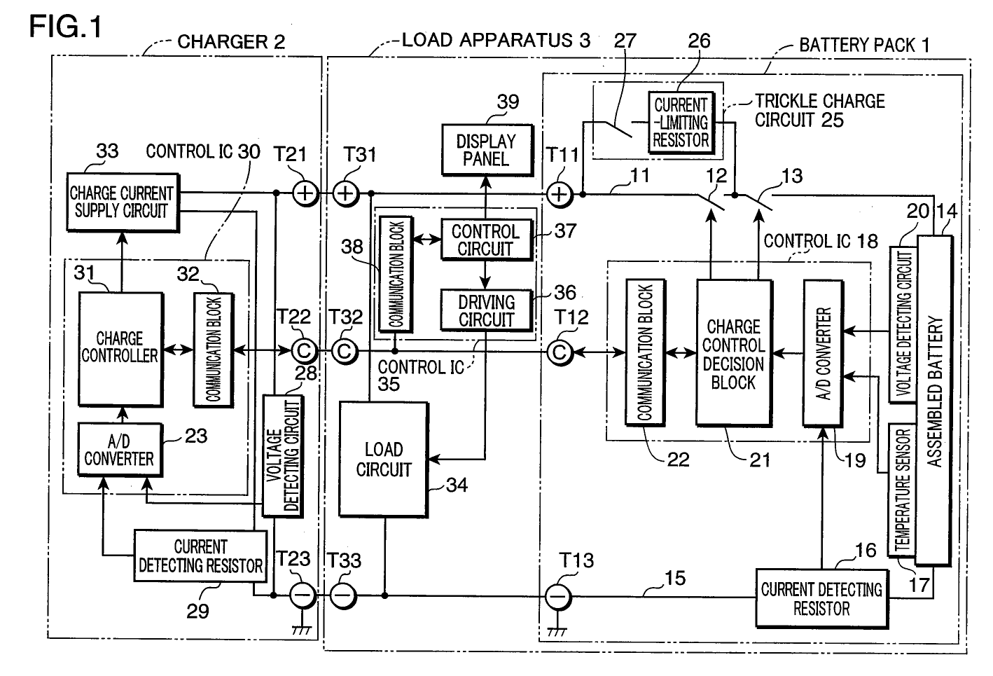

FIG. 1 is a block diagram showing the electrical configuration of an electronic system to which an anomaly detecting method according to a first embodiment of the present invention is applied. This electronic system is configured with a battery pack 1, a charger 2 for charging the battery pack 1 and a load apparatus 3 to which electric power is supplied from the charger 2 or the battery pack 1. The battery pack 1 which is built in the load apparatus 3 or attached to the outside thereof is charged directly from the charger 2 or through the load apparatus 3. The load apparatus 3 which is a personal computer, for example, is made usable while the battery pack 1 is being changed. This means that float charge operation is made possible. The battery pack 1, the charger 2 and the load apparatus 3 are connected together through high-side DC terminals T11, T21, T31 for power supply, terminals T12, T22, T32 for a communication signal and ground (GND) terminals T13, T23, T33 common for the power supply and the communication signal.

In the aforementioned battery pack 1, there are provided FETs 12, 13 having different conductivity types for charging and discharging, respectively, in a high-side DC charge/discharge line 11 extending from the terminal T11 which connects to a high-side terminal of an assembled battery 14. A low-side terminal of the assembled battery 14 is connected to the GND terminal T13 through a low-side DC charge/discharge line 15 in which a current detecting resistor 16 for converting a charge current and a discharge current into voltage values is provided.

The assembled battery 14 is configured with a plurality of series/parallel-connected secondary battery cells of which temperature is detected by a temperature sensor 17 and input into an analog-to-digital converter 19 provided in a control (integrated circuit) IC 18 which constitutes a battery management unit (BMU). Also, a terminal-to-terminal voltage of each cell is read by a voltage detecting circuit 20 and input into the analog-to-digital converter 19 provided in the control IC 18. Further, a current value detected by the current detecting resistor 16 is input into the analog-to-digital converter 19 provided in the control IC 18. The analog-to-digital converter 19 converts individual input values into digital values and outputs the digital values to a charge control decision block 21.

The charge control decision block 21 includes a microcomputer and a peripheral circuit thereof. Responding to individual input values from the analog-to-digital converter 19, the charge control decision block 21 calculates a voltage value, a current value and a pulse width (duty) of a charge current to be output to the charger 2 and outputs these values to the charger 2 from a communication block 22 through the terminals T12, T22, T13, T23. The charge control decision block 21 also performs such protective operation as to turn off the FETs 12, 13 at the occurrence of an anomaly on the exterior of the battery pack 1, such as a short circuit between the terminals T11 and T13 or an abnormal current from the charger 2, or an abnormal temperature increase of the assembled battery 14, based on the individual input values from the analog-to-digital converter 19. When charge or discharge operation is normally performed, the charge control decision block 21 keeps the FETs 12, 13 in an ON state to permit the charge or discharge operation, and when an anomaly is detected, the charge control decision block 21 turns off the FETs 12, 13 to disable the charge or discharge operation.

In the charger 2, a communication block 32 of a control IC 30 receives the aforementioned output request and a charge controller 31 controls a charge current supply circuit 33 to supply the charge current at the aforementioned voltage value, current value and pulse width. Including an AC-DC converter and a DC-DC converter, for instance, the charge current supply circuit 33 converts an input voltage into a voltage having the voltage value, the current value and the pulse width specified by the charge controller 31 and supplies the charge current into the charge/discharge lines 11, 15 through the terminals T21, T11, T23, T13. The voltage between the terminals T21 and T23, and thus the voltage between the terminals T11 and T13 of the battery pack 1, is detected by a voltage detecting circuit 28 and a current supplied into the battery pack 1 or the load apparatus 3 is detected by a current detecting resistor 29. The detected voltage and current are converted into digital values by an analog-to-digital converter 23 and the digital values are input into the charge controller 31.

In the battery pack 1, the high-side DC charge/discharge line 11 is provided with a trickle charge circuit 25 connected in parallel with the normal (quick) charge FET 12. The trickle charge circuit 25 is a series circuit made of a current-limiting resistor 26 and an FET 27. In an early stage of charging or when additionally charging the battery pack 1 in a region near a fully charged state, the charge control decision block 21 turns off the quick charge FET 12 while keeping the discharge FET 13 in the ON state and then turns on the trickle charge FET 27 to perform trickle charge operation. For normal charging and discharging, the charge control decision block 21 turns on the FET 12 while keeping the FET 13 in the ON state and then turns off the FET 27 to perform the charge or discharge operation by flowing a normal current.

If the secondary battery is a lithium ion battery, whether or not to perform the trickle charge operation in the early stage of charging is decided based on whether the terminal-to-terminal voltage of each cell detected by the voltage detecting circuit 20 is equal to or lower than 2.5 V which is an end voltage Vm of the trickle charge operation. If the terminal-to-terminal voltage of each cell exceeds 2.5 V, the trickle charge operation is not performed and quick charge operation is performed from the beginning.

Electric power is supplied to a load circuit 34 of the load apparatus 3 from the terminals T21, T23 on the side of the charger 2 or from the terminals T11, T13 on the side of the battery pack 1 through the terminals T31, T33 on the side of the load apparatus 3. Operation of the load circuit 34 is controlled by a control IC 35. The control IC 35 includes a driving circuit 36 for driving the load circuit 34, a control circuit 37 for driving the load circuit 34 through the driving circuit 36 according to operation of an unillustrated operating unit or the like, a communication block 38 for performing communication with the charger 2 and the battery pack 1 through the terminals T32, T33 and a display panel 39. The control circuit 37 performs such operations as to make a request for the value of a current to be supplied according to operating conditions of the load circuit 34 through the terminals T32, T33 and the terminals T21, T23 to the charge controller 31, or to display the residual capacity in the battery pack 1 transmitted from the charge control decision block 21 through the terminals T12, T13 and the terminals T21, T23 in coordination with the charge controller 31 or the charge control decision block 21.

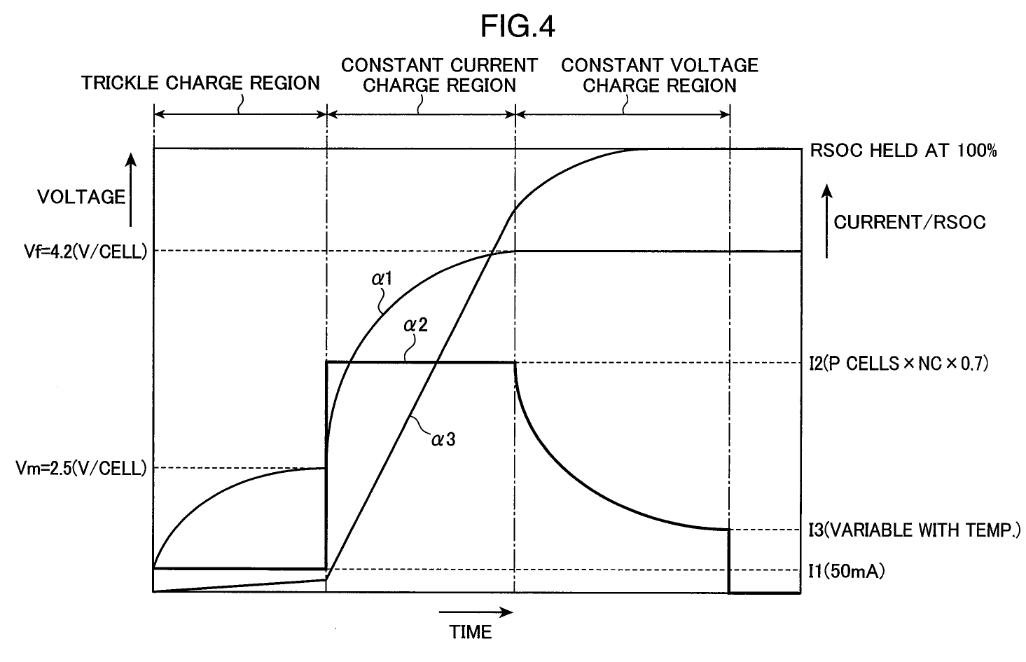

In the electronic system configured as described above, the charge control decision block 21 serving as a charge controller performs charge control operation as previously shown in FIG. 4 by controlling the FETs 12, 13, 27 in the aforementioned manner according to the result of detection by the voltage detecting circuit 20 serving as a voltage detector, the current detecting resistor 16 and the temperature sensor 17 and requesting the charger 2 to provide the voltage value, the current value and the pulse width (duty) of the charge current in executing the charge operation. What is noteworthy in the charge control operation of the present embodiment is that the charge control decision block 21 of the control IC 18 causes the voltage detecting circuit 20 to measure cell voltage by making available a time interval during which the capacity of each cell varies by a specified amount, such as a period of time during which 10% of the capacity of each cell is charged or discharged, in a charge or discharge process and then judges whether or not an internal short circuit exists in the cells or an anomaly exists in the voltage detecting circuit 20 serving as the cell voltage detector depending on whether the amount of change in the measured cell voltage falls within a specified range, such as 50 mV. Specifically, the charge control decision block 21 makes the aforementioned judgment with reference to the cell voltage detected by the voltage detecting circuit 20 and a charge or discharge current detected by the current detecting resistor 16. Using an accumulated value of the residual capacity (RSOC) of the secondary battery shown by the reference symbol α3 in FIG. 4 in the case of charge operation, for example, the charge control decision block 21 judges that neither an internal short circuit of the cells nor an anomaly of the voltage detecting circuit 20 has occurred if the amount of change in the cell voltage measured while the accumulated value of the residual capacity (RSOC) varies by 10% does not fall within the aforementioned specified range. On the other hand, the charge control decision block 21 determines that at least one of an internal short circuit of the cells or an anomaly of the voltage detecting circuit 20 has occurred if the amount of change in the cell voltage measured while the accumulated value of the residual capacity (RSOC) varies by 10% falls within the aforementioned specified range.

If there is neither an internal short circuit of the cells nor an anomaly of the voltage detecting circuit 20 with the amount of change in the cell voltage being out of the specified range, the charge control decision block 21 judges that a below-described fully charged state has been achieved. If the amount of change in the cell voltage is within the specified range, on the contrary, the charge control decision block 21 judges that an internal short circuit has occurred in one of the cells or an anomaly of the voltage detecting circuit 20 has occurred. In this case, the charge control decision block 21 does not judge that the fully charged state has been achieved and, then, turns off the FETs 12, 13 and requests a charge current of 0 A and a charge voltage of 0 V from the charger 2 through the communication block 22 to terminate the charge operation.

If the charge process is switched from constant current (CC) charge to constant voltage (CV) charge and at a point in time when the cell voltage detected by the voltage detecting circuit 20 is equal to or higher than a specific threshold voltage, such as 4.1 V and the charge current value detected by the current detecting resistor 16 drops to a foldback current value I3 which is set in accordance with cell temperature detected by the temperature sensor 17, the charge control decision block 21 judges that the aforementioned fully charged state has been achieved. Upon judging that the fully charged state has been achieved, the charge control decision block 21 turns off the FETs 12,13 and requests a charge current of 0 A and a charge voltage of 0 V from the charger 2 through the communication block 22 and thereby terminates the charge operation. On the other hand, unless the charge process is switched from constant current (CC) charge to constant voltage (CV) charge and the fully charged state is judged to have been achieved, the charge control decision block 21 keeps the charge operation in progress.

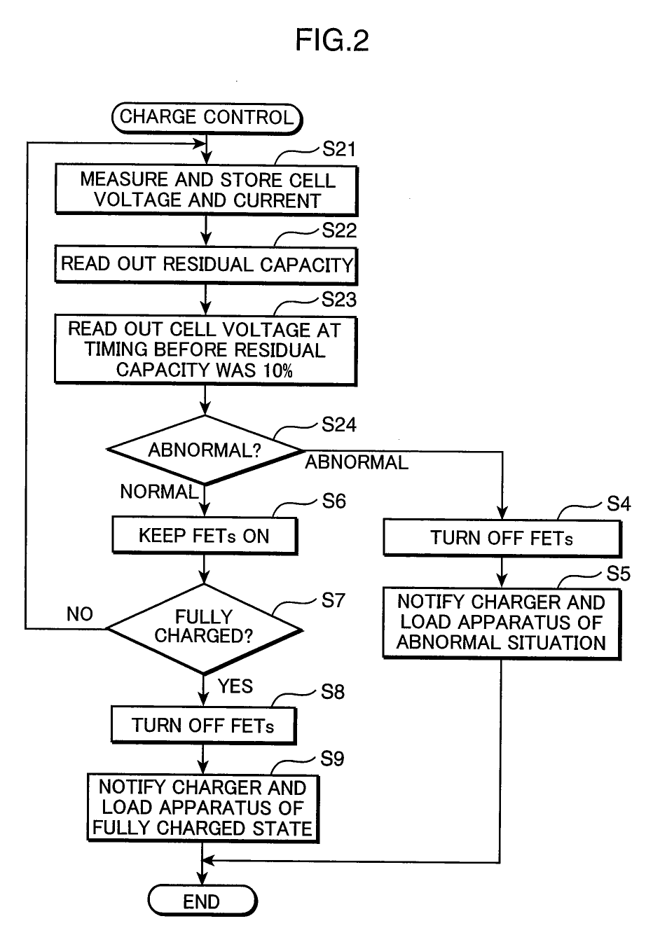

FIG. 2 is a flowchart for explaining anomaly detecting operation performed by the charge control decision block 21. When the charge operation is started, the charge control decision block 21 causes the voltage detecting circuit 20 and the current detecting resistor 16 to measure the cell voltage and the charge current value, respectively, and an unillustrated storage unit to store the cell voltage and the charge current value in step S21. In step S22, the charge control decision block 21 accumulated the residual capacity (RSOC) based on the cell voltage and current. In step S23, the charge control decision block 21 read out the cell voltage measured at a timing before the residual capacity has varied by 10% of the calculated residual capacity (RSOC) from the storage unit. In step S24, the charge control decision block 21 determines whether or not there is an internal short circuit of the cells or an anomaly of the voltage detecting circuit 20 depending on whether a difference between the cell voltages measured before and after the residual capacity (RSOC) has varied by 10% is equal to or smaller than the aforementioned value of 50 mV. If there is an internal short circuit of the cells or an anomaly of the voltage detecting circuit 20, the charge control decision block 21 proceeds to a process of step S4 onward to be carried out in an abnormal situation. In step S4, the charge control decision block 21 turns off the FETs 12, 13, 27 to terminate the charge operation. In succeeding step S5, the charge control decision block 21 requests a charge current of 0 A and a charge voltage of 0 V and notifies the charger 2 of the abnormal situation so that the charger 2 stops supplying the charge current. In step S5, the charge control decision block 21 also notifies the load apparatus 3 of the occurrence of the abnormal situation, whereby the occurrence of the abnormal situation is indicated on the display panel 39 to notify a user of the situation.

On the other hand, if the difference between the cell voltages measured before and after the residual capacity (RSOC) has varied by 10% is out of the specified range in step S24 and, thus, neither an internal short circuit of the cells nor an anomaly of the voltage detecting circuit 20 has occurred, the charge control decision block 21 keeps the FET 13 and the FET 12 or the FET 27 in the ON state to continue the charge operation in step S6. In step S7, the charge control decision block 21 judges whether or not the fully charged state has been achieved with the cell voltage is equal to or higher than the specific threshold voltage and the charge current value dropping to the foldback current value I3. If the fully charged state has been achieved in step S7, the charge control decision block 21 turns off the FETs 12, 13, 27 to terminate the charge operation in step S8. In succeeding step S9, the charge control decision block 21 requests a charge current of 0 A and a charge voltage of 0 V and notifies the charger 2 that the fully charged state has been achieved so that the charger 2 stops supplying the charge current. In step S9, the charge control decision block 21 also notifies the load apparatus 3 that the fully charged state has been achieved, whereby accomplishment of the fully charged state is indicated on the display panel 39 and the above-described operation is completed. If the fully charged state has not been achieved in step S7, the charge control decision block 21 returns to step S1 and continues the charge operation.

If no data is available on the cell voltage measured before the residual capacity has varied by 10% in an early stage of charging, for instance, the charge control decision block 21 may use the cell voltage measured at the beginning of charging or regard that the judgment result in step S24 is in the affirmative (normal) without reading out the cell voltage. In a case where the charge control decision block 21 judges whether or not there is an internal short circuit of the cells or an anomaly of the voltage detecting circuit 20 during discharge operation and decides whether to perform charge operation depending on the result of this judgment as in the anomaly detecting operation illustrated in FIG. 2, the charge control decision block 21 may hold the judgment result in the form of a flag.

According to the above-described configuration, the charge control decision block 21 judges that the fully charged state has been achieved when the cell voltage of the secondary battery becomes equal to or higher than the specific threshold voltage and the charge current value drops to the specific foldback current value I3 to prevent misjudgment related to the float charge operation, and terminates the charge operation. By performing the charge control operation in this fashion, the charge control decision block 21 quickly detects an internal short circuit of the cells or an anomaly of the voltage detecting circuit 20 and prevents in advance continued execution of the charge operation when the cell voltage does not become equal to or higher than the aforementioned threshold voltage due to the internal short circuit of the cells or the anomaly of the voltage detecting circuit 20.

The aforementioned specified range may be determined in consideration of a range of design values from a maximum value to a minimum value thereof. In particular, the specified range may be determined such that the misjudgment would not be made if the amount of change in the cell voltage is small in many cases even when the residual capacity varies by 10%. Also, the specified range may be set to vary according to temperature or the charge current value. Furthermore, sampling intervals of the cell voltage, that is, intervals of anomaly detection, are not limited to the timing at which the residual capacity has varied by 10%. Rather, the occurrence of an anomaly may be judged at shorter intervals when the residual capacity has varied by 5% or 1%, for example, wherein the intervals may be determined depending on the amount of change in the cell voltage and the measuring accuracy of the voltage detecting circuit 20. Moreover, whether or not there is an anomaly may be judged from a mean value of a specific number of data sampled at the aforementioned shorter intervals.

According to the method of detecting a battery pack anomaly and the battery pack of the present embodiment thus far discussed, a time interval during which the capacity of each cell varies by a specified amount, such as a period of time during which 10% of the capacity of each cell is charged or discharged, is made available at least in one of charge and discharge processes to measure the cell voltage and a judgment is made to determine whether or not an internal short circuit exists in the cells or an anomaly exists in the cell voltage detector depending on whether the amount of change in the measured cell voltage falls within a specified range, such as 50 mV.

Accordingly, it is judged that the fully charged state has been achieved when the cell voltage of the secondary battery becomes equal to or higher than the specific threshold voltage and the charge current value drops to the specific foldback current value to prevent misjudgment related to the float charge operation and, in this case, the charge operation is terminated. By performing the charge control operation in this fashion, an internal short circuit of the cells is quickly detected, making it possible to prevent in advance continued execution of the charge operation when conditions for judging that the fully charged state has been achieved (the terminal-to-terminal voltage does not rise up to the specific threshold voltage) are not satisfied.

### Second Embodiment

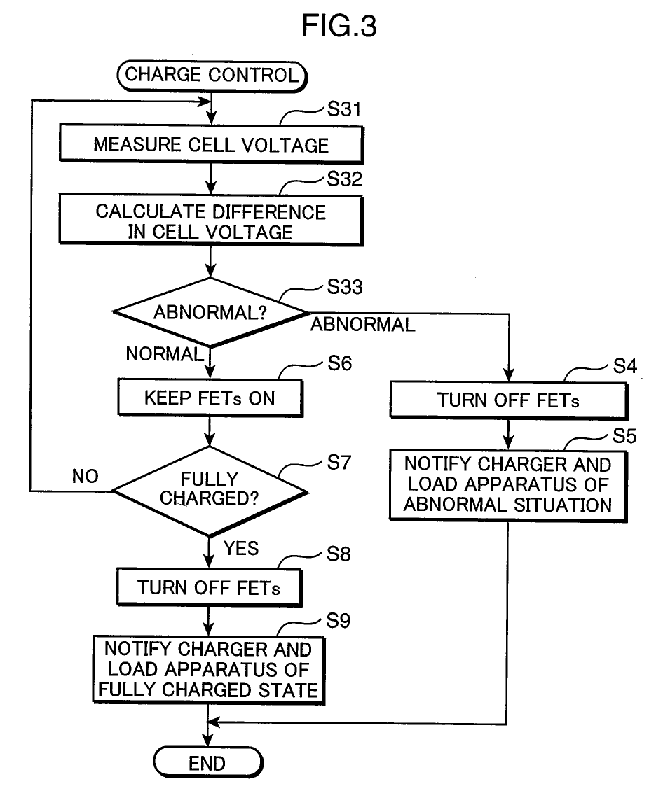

FIG. 3 is a flowchart for explaining anomaly detecting operation according to another embodiment of the present invention. The configuration of the electronic system previously depicted in FIG. 1 can also be used in the present embodiment. What is noteworthy in this embodiment is that the charge control decision block 21 of the control IC 18 causes the voltage detecting circuit 20 to measure the voltage of each cell of the assembled battery 14 which is made up of a plurality of series-connected cells in a charge or discharge process and then judges whether or not an internal short circuit exists in the cells or an anomaly exists in the voltage detecting circuit 20 depending on whether variations of the measured cell voltages fall within a specified range, such as 0.5 V.

When the charge operation is started, the charge control decision block 21 causes the voltage detecting circuit 20 to measure the cell voltage in step S31 and, then, calculates a difference between voltages of one cell and another in step S32. In step S33, the charge control decision block 21 determines whether or not there is an internal short circuit of the cells or an anomaly of the voltage detecting circuit 20 depending on whether the differences between the cell voltages fall within the aforementioned range of 0.5 V. If there is an internal short circuit of the cells or an anomaly of the voltage detecting circuit 20, the charge control decision block 21 proceeds to a process of step S4 onward to be carried out in an abnormal situation. On the other hand, if neither an internal short circuit of the cells nor an anomaly of the voltage detecting circuit 20 exists, the charge control decision block 21 proceeds to a process of step S6 onward to be carried out in a normal situation.

In this configuration, the charge control decision block 21 also judges that the fully charged state has been achieved when the cell voltage of the secondary battery becomes equal to or higher than the specific threshold voltage and the charge current value drops to the specific foldback current value I3 to prevent misjudgment related to the float charge operation, and terminates the charge operation. By performing the charge control operation in this fashion, the charge control decision block 21 quickly detects an internal short circuit of the cells or an anomaly of the voltage detecting circuit 20 and prevents in advance continued execution of the charge operation when the cell voltage does not become equal to or higher than the aforementioned threshold voltage due to the internal short circuit of the cells or the anomaly of the voltage detecting circuit 20.

Japanese Unexamined Patent Publication No. 1999-273750 describes an arrangement in which an alkaline zinc storage battery is charged with a constant current for a specific period of time from a fully discharged state and, if a voltage value at a point in time when the charge operation is completed is lower than a threshold value of the voltage value expected with a normal battery, it is judged that there is an internal short circuit in the battery. Also, paragraph 0043 of the Publication states that this judgment is made by a property evaluation device. Accordingly, this prior art arrangement is intended to check a deteriorated battery at a point of shipment from a factory.

Compared to this prior art arrangement, the present embodiment provides a self-diagnostic function to check a battery pack containing normal cells in real time under practically used conditions (in which a charge or discharge current and time vary flexibly), so that the embodiment has a multi-purpose applicability and completely different object and operational and working effects. Specifically, the embodiment provides the anomaly detecting method which can be used for versatile applications under practical conditions by assuming that measurement of electric current and management of residual capacity are correctly made and using a residual capacity value accumulated between two arbitrary points based on this assumption. This anomaly detecting method makes it possible to detect not only an internal short circuit of a secondary battery but also an anomaly of a voltage measuring system. In the case of a lithium secondary battery which requires that the voltage of each cell be detected, it is not necessary to newly prepare a voltage measuring circuit of each cell for using the anomaly detecting method of the present embodiment, so that the embodiment is particularly preferable as the anomaly detecting method and can easily be applied by simply performing an additional control operation for anomaly detection.

According to the method of detecting a battery pack anomaly and the battery pack of the present embodiment thus far discussed, the voltage of each cell of the secondary battery made up of a plurality of series-connected cells is measured and a judgment is made to determine whether or not an internal short circuit exists in the cells or an anomaly exists in the cell voltage detector depending on whether variations of the measured cell voltages fall within a specified range, such as 0.5 V.

Accordingly, it is judged that the fully charged state has been achieved when the cell voltage of the secondary battery becomes equal to or higher than the specific threshold voltage and the charge current value drops to the specific foldback current value to prevent misjudgment related to the float charge operation and, in this case, the charge operation is terminated. By performing the charge control operation in this fashion, an internal short circuit of the cells is quickly detected, making it possible to prevent in advance continued execution of the charge operation when conditions for judging that the fully charged state has been achieved (the terminal-to-terminal voltage does not rise up to the specific threshold voltage) are not satisfied.

From the individual embodiments thus far discussed, the present invention can be summarized as described hereinbelow. Specifically, an anomaly detecting method of the present invention for a battery pack including a secondary battery made up of at least one cell and a voltage detecting circuit for measuring cell voltage of the secondary battery comprises the steps of measuring the cell voltage, judging by using the measured cell voltage whether predefined anomaly judgment conditions to be used in determining that at least one of an internal short circuit of the cell and an anomaly of the voltage detecting circuit has occurred are satisfied, and determining that at least one of the internal short circuit of the cell and the anomaly of the voltage detecting circuit has occurred if the anomaly judgment conditions are judged to have been satisfied.

In the aforementioned anomaly detecting method, it is judged that at least one of an internal short circuit of the cell and an anomaly of the voltage detecting circuit has occurred by determining whether or not the predefined conditions have been satisfied.

It is preferable that the aforementioned voltage measuring step include the step of measuring the cell voltage at intervals of time during which the capacity of the cell varies by a specified amount in a charge or discharge process, and the aforementioned judging step include the step of judging whether the amount of change in the measured cell voltage falls within a specified range as the anomaly judgment conditions and determining that at least one of the internal short circuit of the cell and the anomaly of the voltage detecting circuit has occurred if the amount of change in the measured cell voltage falls within the specified range.

According to this arrangement, a time interval during which the capacity of each cell varies by a specified amount, such as a period of time during which 10% of the capacity of each cell is charged or discharged, is made available at least in one of charge and discharge processes to measure the cell voltage and a judgment is made to determine whether or not an internal short circuit exists in the cells or an anomaly exists in the voltage detecting circuit depending on whether the amount of change in the measured cell voltage falls within the specified range, such as 50 mV.

Accordingly, it is judged that a fully charged state has been achieved when the cell voltage of the secondary battery becomes equal to or higher than a specific threshold voltage and the value of charge current drops to a specific foldback current value to prevent misjudgment related to float charge operation, and charge operation is terminated. By performing charge control operation in this fashion, an internal short circuit of the cells or an anomaly of a cell voltage detector is quickly detected, making it possible to prevent in advance continued execution of the charge operation when conditions for judging that the fully charged state has been achieved (the terminal-to-terminal voltage does not rise up to the specific threshold voltage) are not satisfied.

It is preferable that the aforementioned intervals of time be defined based on whether a ratio of change of an accumulated value of the capacity of the cell exceeds a specified value.

It is preferable that the aforementioned specified value be 10%.

It is preferable that the aforementioned specified range be 50 mV.

It is preferable that the aforementioned at least one cell include a plurality of series-connected cells, and the aforementioned judging step include the step of judging whether variations of the measured cell voltages fall within a specified range as the anomaly judgment conditions and determining that at least one of the internal short circuit of the cell and the anomaly of the voltage detecting circuit has occurred if the variations of the measured cell voltages fall within the specified range.

According to this arrangement, the voltage of each cell of the secondary battery made up of a plurality of series-connected cells is measured and a judgment is made to determine whether or not an internal short circuit exists in the cells or an anomaly exists in the cell voltage detector depending on whether variations of the measured cell voltages fall within a specified range, such as 0.5 V.

Accordingly, it is judged that the fully charged state has been achieved when the cell voltage of the secondary battery becomes equal to or higher than the specific threshold voltage and the charge current value drops to the specific foldback current value to prevent misjudgment related to the float charge operation and, in this case, the charge operation is terminated. By performing the charge control operation in this fashion, an internal short circuit of the cells or an anomaly of the voltage detecting circuit is quickly detected, making it possible to prevent in advance continued execution of the charge operation when the conditions for judging that the fully charged state has been achieved (the terminal-to-terminal voltage does not rise up to the specific threshold voltage) are not satisfied.

It is preferable that the aforementioned specified range be 0.5 V.

A battery pack according to the present invention comprises a secondary battery made up of at least one cell, a voltage detecting circuit for measuring cell voltage of the secondary battery, and a charge controller for controlling a charge current supplied to the secondary battery in accordance with the result of detection by the voltage detecting circuit. In this battery pack, the charge controller judges by using the cell voltage measured by the voltage detecting circuit whether predefined anomaly judgment conditions to be used in determining that at least one of an internal short circuit of the cell and an anomaly of the voltage detecting circuit has occurred are satisfied and then determines that at least one of the internal short circuit of the cell and the anomaly of the voltage detecting circuit has occurred if the anomaly judgment conditions are judged to have been satisfied.

In the aforementioned battery pack, it is judged that at least one of an internal short circuit of the cell and an anomaly of the voltage detecting circuit has occurred by determining whether or not the predefined conditions have been satisfied.

It is preferable that the charge controller cause the voltage detecting circuit to measure the cell voltage at intervals of time during which the capacity of the cell varies by a specified amount in a charge or discharge process, judge whether the amount of change in the measured cell voltage falls within a specified range as the anomaly judgment conditions and determine that at least one of the internal short circuit of the cell and the anomaly of the voltage detecting circuit has occurred if the amount of change in the measured cell voltage falls within the specified range.

According to this arrangement, a time interval during which the capacity of each cell varies by a specified amount, such as a period of time during which 10% of the capacity of each cell is charged or discharged, is made available at least in one of charge and discharge processes to measure the cell voltage and a judgment is made to determine whether or not an internal short circuit exists in the cells or an anomaly exists in the voltage detecting circuit depending on whether the amount of change in the measured cell voltage falls within the specified range, such as 50 mV.

Accordingly, it is judged that a fully charged state has been achieved when the cell voltage of the secondary battery becomes equal to or higher than a specific threshold voltage and the value of charge current drops to a specific foldback current value to prevent misjudgment related to float charge operation, and charge operation is terminated. By performing charge control operation in this fashion, an internal short circuit of the cells or an anomaly of the voltage detecting circuit is quickly detected, making it possible to prevent in advance continued execution of the charge operation when conditions for judging that the fully charged state has been achieved (the terminal-to-terminal voltage does not rise up to the specific threshold voltage) are not satisfied.

It is preferable that the aforementioned intervals of time be defined based on whether a ratio of change of an accumulated value of the capacity of the cell exceeds a specified value.

It is preferable that the aforementioned specified value be 10%.

It is preferable that the aforementioned specified range be 50 mV.

It is preferable that the aforementioned at least one cell include a plurality of series-connected cells, and the charge controller cause the voltage detecting circuit to measure the cell voltage a plurality of times, judge whether variations of the measured cell voltages fall within a specified range as the anomaly judgment conditions and determine that at least one of the internal short circuit of the cell and the anomaly of the voltage detecting circuit has occurred if the variations of the measured cell voltages fall within the specified range.

According to this arrangement, the voltage of each cell of the secondary battery made up of a plurality of series-connected cells is measured and a judgment is made to determine whether or not an internal short circuit exists in the cells or an anomaly exists in the cell voltage detector depending on whether variations of the measured cell voltages fall within a specified range, such as 0.5 V.

Accordingly, it is judged that the fully charged state has been achieved when the cell voltage of the secondary battery becomes equal to or higher than the specific threshold voltage and the charge current value drops to the specific foldback current value to prevent misjudgment related to the float charge operation and, in this case, the charge operation is terminated. By performing the charge control operation in this fashion, an internal short circuit of the cells or an anomaly of the voltage detecting circuit is quickly detected, making it possible to prevent in advance continued execution of the charge operation when the conditions for judging that the fully charged state has been achieved (the terminal-to-terminal voltage does not rise up to the specific threshold voltage) are not satisfied.

It is preferable that the aforementioned specified range be 0.5 V.

### INDUSTRIAL APPLICABILITY

In a battery pack of the present invention of which residual capacity in percentage is accumulated for indicating the residual capacity, for instance, it is judged that cell voltage does not vary due to an internal short circuit of occurring in cells or an anomaly occurring in a voltage detecting circuit if the amount of change in the cell voltage during a period of time when the accumulated residual capacity percentage varies by a specific value falls within a specified range. Thus, it is judged that a fully charged state has been achieved when the cell voltage of a secondary battery becomes equal to or higher than a specific threshold voltage and the value of charge current drops to a specific foldback current value to prevent misjudgment related to float charge operation, and charge operation is terminated. By performing the charge control operation in this fashion, an internal short circuit of the cells or an anomaly of the voltage detecting circuit is quickly detected, making it possible to prevent in advance continued execution of the charge operation when conditions for judging that the fully charged state has been achieved are not satisfied, so that the present invention is preferably applicable.

1. An anomaly detecting method for a battery pack including a secondary battery made up of at least one cell and a voltage detecting circuit for measuring cell voltage of said secondary battery, said battery pack anomaly detecting method comprising the steps of:
measuring said cell voltage; and
judging by using said measured cell voltage whether predefined anomaly judgment conditions to be used in determining that at least one of an internal short circuit of said cell and an anomaly of said voltage detecting circuit has occurred are satisfied, and determining that at least one of the internal short circuit of said cell and the anomaly of said voltage detecting circuit has occurred if the anomaly judgment conditions are judged to have been satisfied.

2. The battery pack anomaly detecting method according to claim 1, wherein said voltage measuring step includes the step of measuring said cell voltage at intervals of time during which the capacity of said cell varies by a specified amount in a charge or discharge process, and said judging step includes the step of judging whether the amount of change in said measured cell voltage falls within a specified range as said anomaly judgment conditions and determining that at least one of the internal short circuit of said cell and the anomaly of said voltage detecting circuit has occurred if the amount of change in said measured cell voltage falls within said specified range.

3. The battery pack anomaly detecting method according to claim 2, wherein said intervals of time are defined based on whether a ratio of change of an accumulated value of the capacity of said cell exceeds a specified value.

4. The battery pack anomaly detecting method according to claim 3, wherein said specified value is 10%.

5. The battery pack anomaly detecting method according to claim 2, wherein said specified range is 50 mV.

6. The battery pack anomaly detecting method according to claim 1, wherein said at least one cell includes a plurality of series-connected cells, and said judging step includes the step of judging whether variations of said measured cell voltages fall within a specified range as said anomaly judgment conditions and determining that at least one of the internal short circuit of said cell and the anomaly of said voltage detecting circuit has occurred if the variations of said measured cell voltages fall within said specified range.

7. The battery pack anomaly detecting method according to claim 6, wherein said specified range is 0.5 V.

8. A battery pack comprising:
a secondary battery made up of at least one cell;
a voltage detecting circuit for measuring cell voltage of said secondary battery; and
a charge controller for controlling a charge current supplied to said secondary battery in accordance with the result of detection by said voltage detecting circuit;
wherein said charge controller judges by using the cell voltage measured by said voltage detecting circuit whether predefined anomaly judgment conditions to be used in determining that at least one of an internal short circuit of said cell and an anomaly of said voltage detecting circuit has occurred are satisfied and then determines that at least one of the internal short circuit of said cell and the anomaly of said voltage detecting circuit has occurred if the anomaly judgment conditions are judged to have been satisfied.

9. The battery pack according to claim 8, wherein said charge controller causes said voltage detecting circuit to measure said cell voltage at intervals of time during which the capacity of said cell varies by a specified amount in a charge or discharge process, judges whether the amount of change in said measured cell voltage falls within a specified range as said anomaly judgment conditions and determines that at least one of the internal short circuit of said cell and the anomaly of said voltage detecting circuit has occurred if the amount of change in said measured cell voltage falls within said specified range.

10. The battery pack according to claim 9, wherein said intervals of time are defined based on whether a ratio of change in an accumulated value of the capacity of said cell exceeds a specified value.

11. The battery pack according to claim 10, wherein said specified value is 10%.

12. The battery pack according to claim 9, wherein said specified range is 50 mV.

13. The battery pack according to claim 8, wherein said at least one cell includes a plurality of series-connected cells, and said charge controller causes said voltage detecting circuit to measure said cell voltages, judges whether variations of said measured cell voltages fall within a specified range as said anomaly judgment conditions and determines that at least one of the internal short circuit of said cell and the anomaly of said voltage detecting circuit has occurred if the variations of said measured cell voltages fall within said specified range.

14. The battery pack according to claim 13, wherein said specified range is 0.5 V.
